(19) United States
(12) Patent Application Publication
(10) Pub. No.: US 2010/0155911 A1
(43) Pub. Date: Jun. 24, 2010

(54) ESD Protection Diode in RF pads

(75) Inventor: Ramachandran Venkatasubramanian, Phoenix, AZ (US)

Correspondence Address: STERNE, KESSLER, GOLDSTEIN & FOX P.L.L.C., 1100 NEW YORK AVENUE, N.W., WASHINGTON, DC, 20005, US

(73) Assignee: Broadcom Corporation, Irvine, CA (US)

(21) Appl. No.: 12/453,067

(22) Filed: Apr. 28, 2009

Related U.S. Application Data
(60) Provisional application No. 61/138,740, filed on Dec. 18, 2008.

(51) Int. Cl. H01L 29/861; H01L 21/329

(52) U.S. Cl. 257/653; 438/478; 257/E29.327; 257/E21.352; 361/56

(57) ABSTRACT

A diode is provided. The diode includes first and second diffusion layers formed in a substrate, a first metal coupled to the first diffusion layer, and a second metal coupled to the second diffusion layer that has width that is smaller than a width of the second diffusion layer.

### CROSS REFERENCE TO RELATED APPLICATIONS

This application claims the benefit of U.S. Provisional Appl. No. 61/138,740, filed Dec. 18, 2008, which is incorporated by reference herein in its entirety.

### BACKGROUND OF THE INVENTION

1. Field of the Invention

The present invention deals with the layout of circuit elements used in a variety of applications, such as ESD protection.

2. Background Art

Electrostatic discharge (ESD) events result in high voltage and current transients that can damage electrical devices. For example, if these transient voltages and currents are not safely discharged, they can generate heat. This generated heat can, for example, damage elements of an integrated circuit (IC). Thus, a goal of ESD protection devices is to facilitate the safe discharge of ESD event transients.

The resistance of the discharge path is an important factor in designing an ESD protection device. ESD transients generate less heat and are less likely to cause damage to IC blocks when they are discharged through low-resistance paths. In designing devices that can be used to provide a discharge path, many different types of circuit elements can be used. For example, a diode may be used to provide a discharge path. Large diodes tend to have low resistance, and thus are often used in ESD protection applications. However, large diodes also tend to have high stray capacitance. Such capacitance can have a negative effect on circuit blocks and pins to which the diode is coupled. For example, high capacitance can be especially problematic for RF circuit blocks.

What is needed, then, is a diode geometry that has both low resistance and low capacitance.

### BRIEF SUMMARY

A diode is provided. In an embodiment, the diode includes first and second diffusion layers formed in a substrate, a first metal coupled to the first diffusion layer, and a second metal coupled to the second diffusion layer that has width that is smaller than a width of the second diffusion layer.

In another embodiment, a method of forming a diode is provided. The method includes forming a first diffusion layer in a substrate, forming a second diffusion layer in the substrate, coupling a first metal to the first diffusion layer, and coupling a second metal to the second diffusion layer that has width that is smaller than a width of the second diffusion layer.

These and other advantages and features will become readily apparent in view of the following detailed description of the invention. Note that the Summary and Abstract sections may set forth one or more, but not all exemplary embodiments of the present invention as contemplated by the inventor(s).

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

FIG. 1 shows a layout of a conventional diode.

FIG. 2 shows a zoomed-in view of a layout of a conventional diode.

FIG. 3 shows a zoomed-in view of a layout of a diode, according to an embodiment of the present invention.

FIG. 4 shows a cross-sectional view of a diode, according to an embodiment of the present invention.

FIG. 5 shows a cross-sectional view of a diode, according to an embodiment of the present invention.

FIG. 6 shows a flowchart providing example steps for forming a diode, according to an embodiment of the present invention.

The present invention will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION OF THE INVENTION

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

Electrostatic discharge (ESD) protection circuits allow for the safe discharge of ESD event transients between two pins of interest. Diodes can be used to provide ESD protection by coupling pins together to facilitate the safe discharge of ESD event transients. In general, it is desirable that the discharge path have a low resistance. Such a low resistance path can prevent heat generation that can damage integrated circuit (IC) components. Large diodes tend to have low resistance, and thus are often used to provide a discharge path. However, these large diodes tend to also have high stray capacitance that adversely affects circuit blocks to which they are coupled.

ESD protection circuits are often used with radio frequency (RF) circuit blocks. Pins of an IC package that are coupled to RF circuit blocks are often sensitive to stray capacitance. Large diodes that are useful in ESD protection circuits because of their low resistance can present problems for RF circuit blocks because of their high stray capacitance. Thus, to effectively provide ESD protection for an RF circuit block, a diode is needed that has low stray capacitance so that the RF pins are not adversely affected, and also has low resistance so that ESD event transients can be safely discharged.

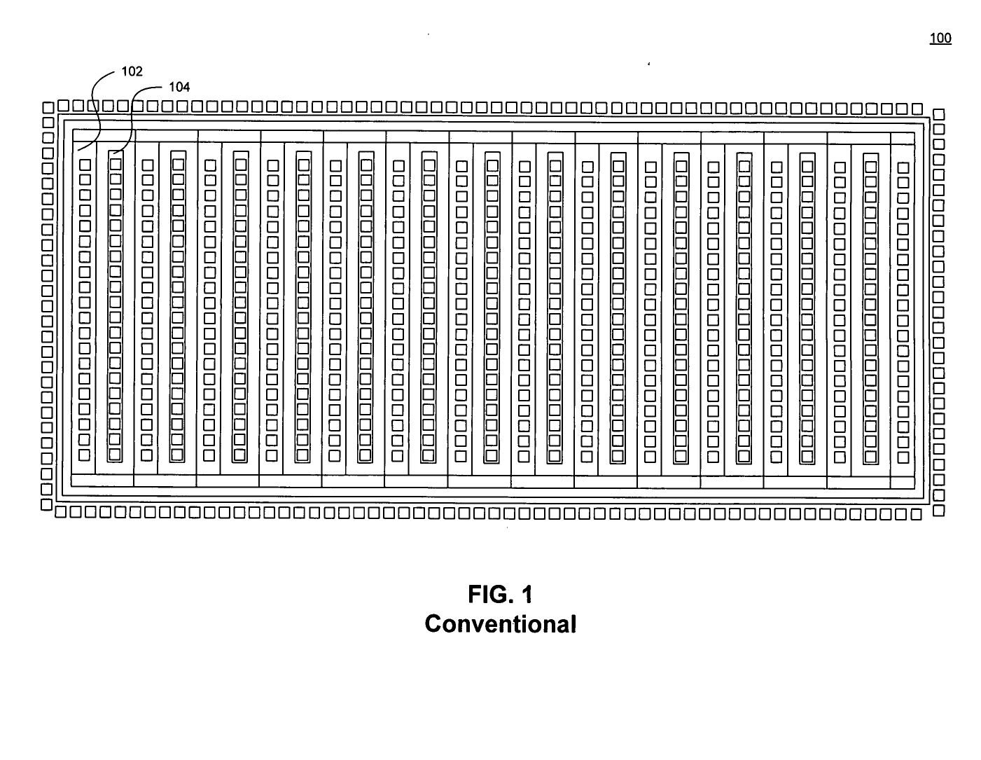

FIG. 1 shows a layout of a conventional diode 100. Diode 100 includes n-type fingers 102 and p-type fingers 104. As shown in FIG. 1, n-type fingers 102 and p-type fingers 104 are arranged in an alternating striped pattern.

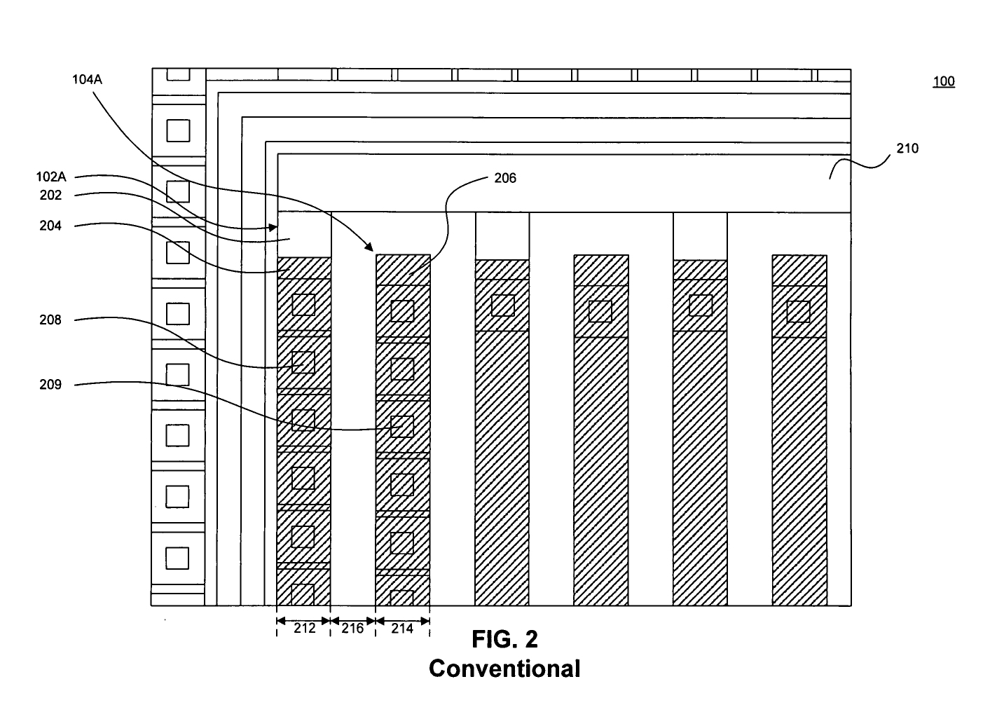

FIG. 2 shows a zoomed-in view of a layout of diode 100. As shown in FIG. 2, diode 100 includes an n-type finger 102A of n-type fingers 102 and a p-type finger 104A of p-type fingers 104. N-type finger 102A includes an n+ diffusion layer 202 coupled to a metal 204 via one or more contacts 208. Similarly, p-type finger 104A includes a p+ diffusion layer (not shown) coupled to a metal 206 via one or more contacts 209. Other n-type fingers 102 and p-type fingers 104 of diode 100 have similar structures as n-type finger 102A and p-type finger 104A, respectively. N-type fingers 102 are coupled together with an n+ diffusion layer 210. In an embodiment, n+ diffusion layers of fingers 102 and p+ diffusion layers of p-type fingers 104 can be formed in a substrate by known doping methods. In a further embodiment, n+ diffusion layer 202 of n-type finger 102A and the p+ diffusion layer of p-type finder 104A are formed in an n-well.

In an embodiment, metals of n-type fingers 102 can be coupled together to form a cathode of diode 100. Similarly, metals of p-type fingers 104 can be coupled together to form an anode of diode 100. As shown in FIG. 2, metal 204 has a width 212 that is equal to the width of n+ diffusion layer 202. Similarly, metal 206 has a width 214 equal to the width of the p+ diffusion layer of p-type finger 104A. In a further embodiment, width 212 of metal 204 can be substantially equal to width 214 of metal 206. For example, widths 212 and 214 can be approximately 0.23 μm. A distance 216 separates n-type finger 102A and p-type finger 104A. Distance 216 can be approximately 0.18 μm. In an embodiment, distance 216 between n-type finger 102A and p-type finger 104A is minimized to reduce the resistance of diode 100. Since widths 212 and 214 are equal to the widths of n+ diffusion layer 202 of finger 102A and the p+ diffusion layer of finger 104A, the distance between metals 204 and 206 is equal to the distance between n+ diffusion layer 202 of finger 102A and the p+ diffusion layer of finger 104A. Reducing distance 216 brings metal 204 closer to metal 206, thereby increasing the metal fringe capacitance of diode 100. Thus, the geometry of striped diode 100 tends to create a tradeoff between fringe capacitance, which affects RF pins coupled to diode 100, and resistance, which affects how effective diode 100 is at discharging ESD event transients.

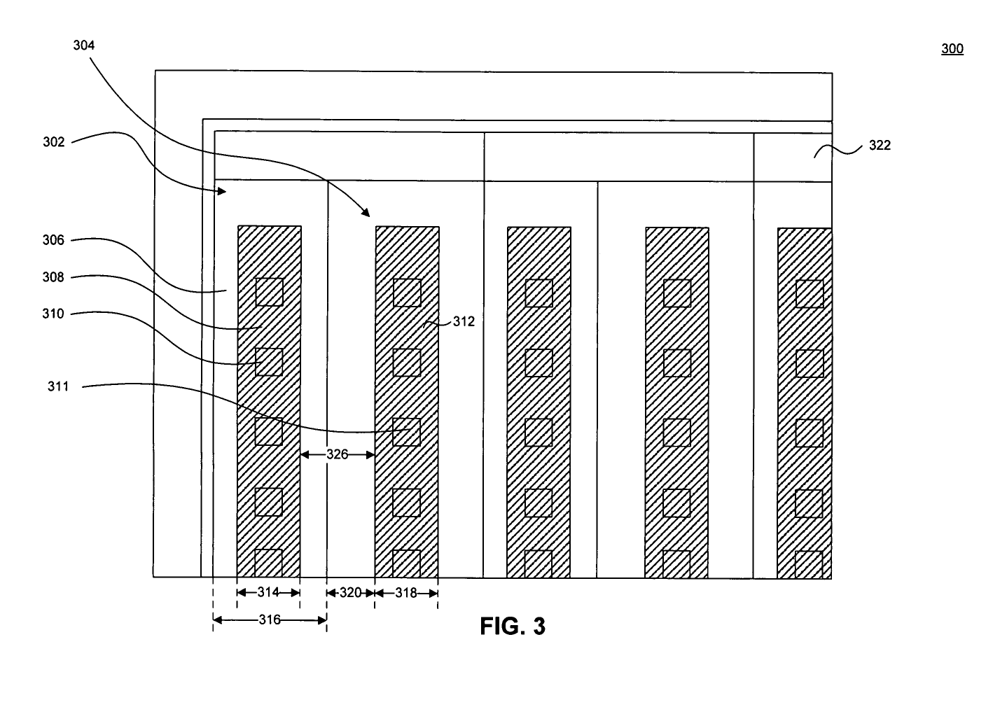

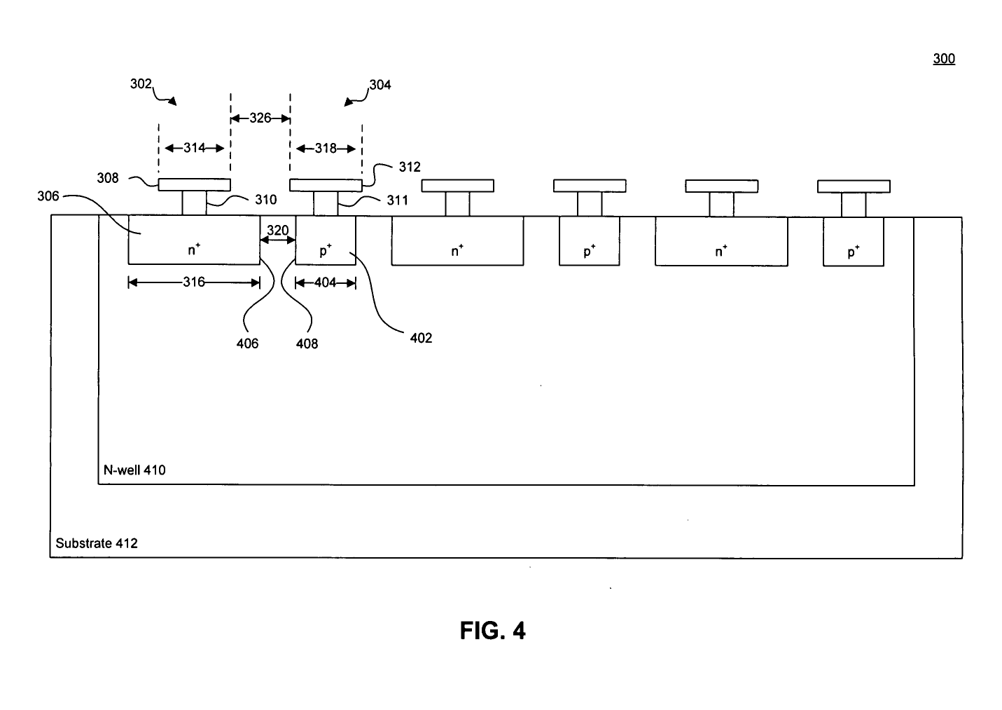

FIG. 3 shows a zoomed-in view of a layout of a diode 300, according to an embodiment of the present invention. FIG. 4 shows a cross sectional view of diode 300. Diode 300 includes a n-type finger 302 and a p-type finger 304. N-type finger 302 includes a n+ diffusion layer 306 coupled to metal 308 via contacts 310. P-type finger 304 includes a p+ diffusion layer (not shown in FIG. 3, labeled as 402 in FIG. 4) coupled to a metal 312 via contacts 311. As shown in FIG. 4, n-type finger 302 and p-type finger 304 are formed in an n-well 410 of a substrate 412.

N+ diffusion layer 306 of n-type finger 302 has a width 316. In an embodiment, width 316 is approximately equal to 0.43 μm. Width 316 can be larger than width 212 of n+ diffusion layer 202 of n-type finger 102A, shown in FIG. 2. Moreover, as shown in FIGS. 3 and 4, width 316 is larger than a width 314 of metal 308. P+ diffusion layer 402 has a width 404 that can be substantially equal to a width 318 of metal 312. In a further embodiment, widths 318 and 404 can be approximately 0.23 μm. In alternate embodiments, width 404 may be different than width 316. Distance 320 separates n-type finger 302 and p-type finger 304. Specifically, distance 320 separates an edge 406 of n+ diffusion layer 306 from an edge 408 of p+ diffusion layer 402. In an embodiment, distance 320 is approximately equal to 0.18 μm.

As current travels horizontally across it, the resistance of diode 300 directly depends on: (1) the distance from contacts 310 of finger 302 to edge 406 of n+ diffusion layer 306, (2) distance 320, and (3) the distance from edge 408 of p+ diffusion layer 402 to contacts 311 of p-type finger 304. Of these three distances, the inventors have found that distance 320 has the most impact on the resistance of diode 300. The resistance of diode 300 can also depend on other factors such as the composition of metals 308 and 312 and the doping levels of n+ diffusion layer 306 and p+ diffusion layer 402.

The metal fringe capacitance inversely depends on a distance 326 between metal 308 of n-type finger 302 and metal 312 of p-type finger 304. In conventional striped diodes, the distance between metals of adjacent fingers is equal to the distance between the respective n+ and p+ diffusion layers. For example, in the embodiment of diode 100, the distance between n+ diffusion layer 202 of n-type finger 102A and the p+ diffusion layer of p-type finger 104A is approximately equal to the distance between metals 204 and 206. Increasing this distance results in an increased resistance, and thus poorer ESD performance. Decreasing this distance results in an increased metal fringe capacitance, and thus poorer performance of pins of the IC package coupled to RF circuit blocks. Accordingly, designers of diodes to be used to provide ESD protection to RF circuit blocks typically choose a distance between adjacent fingers that balances the need for ESD protection and RF performance. The inventors have discovered, however, that by increasing width 316 of n+ diffusion layer 306 relative to width 314 metal 308 providing a diode with relatively low resistance and relatively low stray capacitance. In particular, increasing width 316 allows distance 320 between n+ diffusion layer 306 and p+ diffusion layer 402 to be at least somewhat independent of distance 326 between metals 308 and 312. Accordingly, distance 320, i.e., factor (2) of the resistance listed above, can be determined so as to minimize the resistance, and distance 326 can be independently determined so as to minimize the metal fringe capacitance. Thus, by making width 316 of n+ diffusion layer 306 larger than width 314 of metal 308, distance 320 between n+ diffusion layer 316 and p+ diffusion layer 402 can be determined independently of distance 326 between metals 308 and 312. Accordingly, a diode having both a low resistance and a low fringe capacitance can be provided.

Furthermore, the inventors have also found that the diffusion capacitance of diode 300 at least partially depends on width 404 of p+ diffusion region 402. In an embodiment, then, width 404 is kept at a minimum, e.g., equal to width 318 of metal 312, to limit the diffusion capacitance.

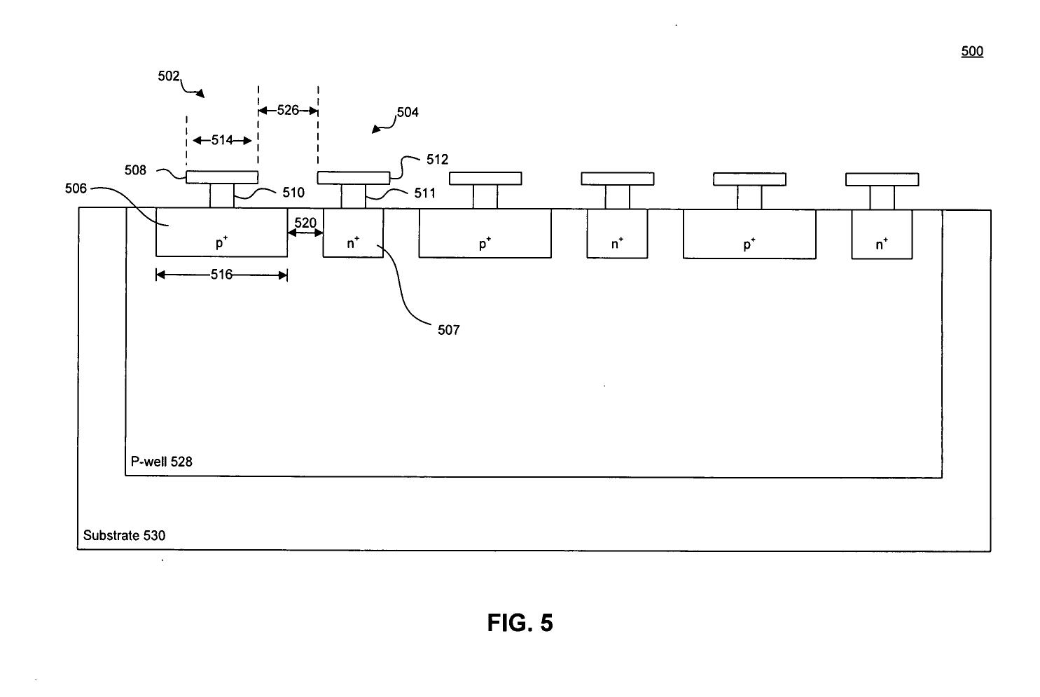

Although, FIGS. 3 and 4 show an embodiment of diode 300 that includes an expanded n+ diffusion layer along with a p+ diffusion layer formed in an n-well, the inventors have contemplated variations without departing from the scope and spirit of the present invention. For example, FIG. 5 shows a cross-sectional view of a diode 500, according to an embodiment of the present invention. Diode 500 includes a p-type finger 502 and an n-type finger 504. P-type finger 502 includes a p+ diffusion layer 506 coupled to a metal 508 through contacts 510. N-type finger 504 includes a n+ diffusion layer 507 coupled to a metal 512 through contacts 511. Fingers 502 and 504 are formed in a p-well 528 of a substrate 530.

As shown in FIG. 5, a width 516 of p+ diffusion layer 506 is smaller than a width 514 of metal 508. Thus, a distance 526 between metals 508 and 512 can be determined independently of distance 520 between p+ diffusion layer 506 and n+ diffusion layer 507. Thus, similar to diode 300 shown in FIGS. 3 and 4, the distances between adjacent metals and between adjacent diffusion regions in diode 500 can be independently determined so as to provide a diode that has both a low resistance and a low fringe capacitance.

In the embodiments of diodes 300 and 500, the n+ and p+ diffusion layers are formed in either a n-well or a p-well. In another embodiment, the n+ diffusion layer and the p+ diffusion layer may be formed in respective n+ and p+ wells. In still another embodiment, a deep n-well may also be used. In another embodiment, n+ and p+ diffusion layers are formed directly on the substrate.

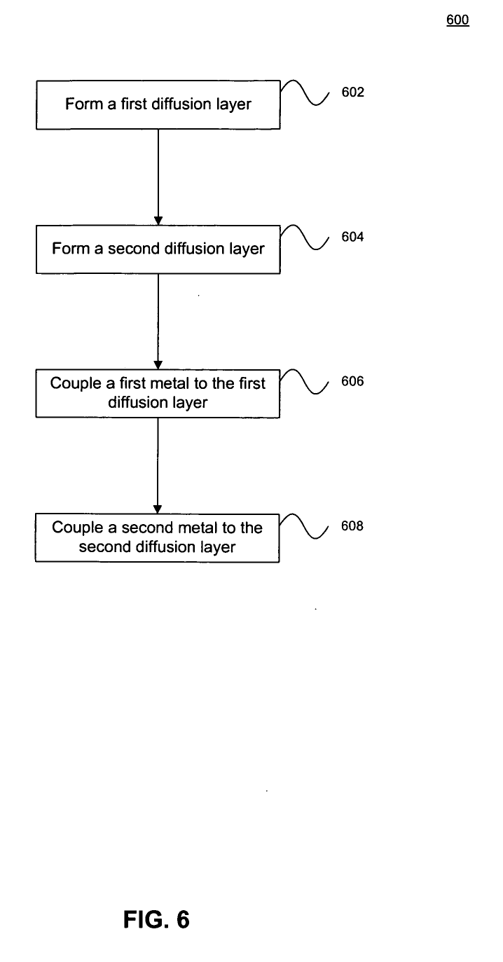

FIG. 6 shows a flowchart 600 providing a method of forming a diode, according to an embodiment of the present invention. Other structural and operational embodiments will be apparent to persons skilled in the relevant art(s) based on the following discussion. The steps shown in FIG. 6 do not necessarily have to occur in the order shown. The steps of FIG. 5 are described in detail below.

In step 602, a first diffusion layer is formed. For example, as shown in FIGS. 3 and 4, an n+ diffusion layer 306 may be formed in an n-well 404 of substrate 406. In an embodiment, the first diffusion layer can be formed by using a known doping method. Also, as shown in FIG. 5, p+ diffusion layer 506 is formed in p-well 528 of substrate 530.

In step 604, the second diffusion layer is formed. For example, in FIG. 4, p+ diffusion layer 402 is formed. In an embodiment, the second diffusion layer is formed using one of many known doping methods. Also, for example, in FIG. 5, a n+ diffusion layer 507 is formed in p-well 528 of substrate 530.

In step 606 a first metal is coupled to the first diffusion layer. For example, in FIGS. 3 and 4, metal 308 is coupled to n+ diffusion layer 306 via a contacts 310. As shown in FIG. 4, metal 308 has a width 314 that is smaller than the width 316 of n+ diffusion layer 306. Also, for example, in FIG. 5, metal 508 is coupled to p+ diffusion layer 506 via contacts 510. Width 514 of metal 508 is smaller than width 516 of p+ diffusion layer 516.

In step 608, a second metal is coupled to the second diffusion layer. For example, in FIGS. 3 and 4, metal 312 is coupled to p+ diffusion layer 402 via contacts 310. Also, for example, metal 512 is coupled to n+ diffusion layer 507 via contacts 511.

### CONCLUSION

While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

What is claimed is:

1. A diode, comprising:
first and second diffusion layers formed in a substrate;
a first metal coupled to the first diffusion layer; and
a second metal coupled to the second diffusion layer that has width that is smaller than a width of the second diffusion layer.

2. The diode of claim 1, wherein the first diffusion layer is a n-type or a p-type diffusion layer.

3. The diode of claim 1, wherein the second diffusion layer is a n-type or a p-type diffusion layer.

4. The diode of claim 1, further comprising:
a first plurality of contacts coupled to the first diffusion layer and the first metal; and
a second plurality of contacts coupled to the second diffusion layer and the second metal.

5. The diode of claim 1, further comprising:
a third diffusion layer, wherein the third diffusion layer is adjacent to the second diffusion layer and wherein the third diffusion layer and the first diffusion layer are of the same type.

6. The diode of claim 1, wherein the diode comprises:
a first plurality of diffusion layers including the first diffusion layer;
a second plurality of diffusion layers including the second diffusion layer;
a first plurality of metals including the first metal, each metal of the first plurality of metals being coupled to a respective diffusion layer of the first plurality of diffusion layers;
a second plurality of metals including the second metal, each metal of the second plurality of metals being coupled to a respective diffusion layer of the second plurality of diffusion layers, wherein each metal of the second plurality of metals has a width that is smaller than a width of the respective diffusion layer of the second plurality of diffusion layers;
wherein diffusion layers of the first plurality of diffusion layers are of a first type and diffusion layers of the second plurality of diffusion layers are of a second type and wherein diffusion layers of the first plurality of diffusion layers are located between respective diffusion layers of the second plurality of diffusion layers.

7. The diode of claim 1, wherein a width of the first metal is substantially equal to a width of the first diffusion layer.

8. The diode of claim 1, wherein the width of the first metal is substantially equal to the width of the second metal.

9. The diode of claim 1, wherein the first and second diffusion layers are formed in a n-well or a p-well of the substrate.

10. The diode of claim 1, wherein the first and second diffusion layers have a substantially rectangular cross-section.

11. The diode of claim 1, wherein the width of the second diffusion layer is larger than a width of the first diffusion layer.

12. A method of forming a diode, comprising:
(a) forming a first diffusion layer in a substrate;
(b) forming a second diffusion layer in the substrate;
(c) coupling a first metal to the first diffusion layer; and
(d) coupling a second metal to the second diffusion layer that has width that is smaller than a width of the second diffusion layer.

13. The method of claim 12, further comprising:
(e) forming a first plurality of contacts coupled to the first diffusion layer, wherein step (c) comprises coupling the first metal to the first plurality of contacts; and
(f) forming a second plurality of contacts coupled to the second diffusion layer, wherein step (d) comprises coupling the second metal to the second plurality of contacts.

14. The method of claim 12, further comprising:
(e) forming a third diffusion layer adjacent to the second diffusion layer, wherein the third diffusion layer and the first diffusion layer are of the same type.

15. The method of claim 12, wherein step (b) comprises:
forming the second diffusion layer such that the width of the second diffusion layer is larger than a width of the first diffusion layer.
